(19) United States
(12) Patent Application Publication
(10) Pub. No.: US 2008/0054353 A1
(43) Pub. Date: Mar. 6, 2008

(54) SEMICONDUCTOR DEVICE AND METHOD OF MANUFACTURING THE SAME

(75) Inventors: Ho-Jin OH, Seoul (KR); Sung-Sam LEE, Gyeonggi-do (KR); Bong-Cheol KIM, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/849,900

(22) Filed: Sep. 4, 2007

(30) Foreign Application Priority Data
Sep. 4, 2006 (KR) 2006-0084855

(51) Int. Cl. H01L 29/78; H01L 21/336; H01L 29/06

(52) U.S. Cl. 257/334; 257/618; 438/270; 257/E29.262; 257/E21.41

(57) ABSTRACT

A semiconductor device includes a semiconductor substrate and recess trenches formed on the semiconductor substrate. The recess trenches are arranged to extend along a first direction. Terminal regions of adjacent ones of the recess trenches are offset relative to each other along a second direction substantially perpendicular to the first direction.

### CROSS REFERENCE TO RELATED APPLICATION

This application claims the benefit of foreign priority to Korean Patent Application No. 10-2006-0084855 filed on Sep. 4, 2006, the disclosure of which is incorporated herein by reference in its entirety.

### BACKGROUND

1. Field of Invention

Embodiments of the present invention relate generally to semiconductor devices and methods of manufacturing the same. In particular, embodiments of the present invention relate to a semiconductor device and a method of manufacturing the same with increased productivity.

2. Description of the Related Art

With large scale integration of semiconductor devices, MOS devices are reduced in size more and more. To improve operational speeds and current driving capacity, channel lengths of MOS devices have been decreased to deep sub-micron ranges.

As the channel length decreases, a depletion region of a source electrode and a drain electrode enters the channel. As a result, an active channel length of the MOS transistor is reduced. For this reason, a threshold voltage is reduced, which causes a short channel effect that a gate control function in a MOS transistor is lost. In addition, upon operating the MOS transistor, impurities of the source electrode and the drain electrode become overly diffused. As a result, an undesirable punch-through effect occurs.

As a design rule is reduced, a leakage current due to the short channel effect and an increase of an ion implantation amount increases, which makes it difficult to secure an adequate refresh time. Accordingly, to secure a sufficient channel length, a recess channel array transistor (RCAT) has been proposed to increase channel lengths of transistors by forming a recess channel trench in regions where channels of transistors are to be formed.

Generally, when manufacturing the recess channel array transistor, a plurality of recess trenches extend along the same direction. The recess trenches are typically formed using an etching process. However, an etching amount at a terminal region of each of the recess trenches may be larger than etching amounts in other regions. Accordingly, a width of the terminal region of recess trenches may be larger than widths of other regions of the recess trenches. As a result, adjacent recess trenches may be connected to each other via their respective terminal regions and a bridge may occur. Bridges can cause short circuiting of the semiconductor device, which may result in a defective semiconductor device. As the percent of defective semiconductor devices increases, the productivity of the semiconductor device decreases.

Moreover, spherical recess trenches have spherical bottoms wherein the width of a lower part of the spherical recess trench is larger than the width in the general recess trench, the bridge may easily occur.

### SUMMARY

Some embodiments of the present invention can be characterized as providing a semiconductor device that can increase productivity. Further embodiments of the present invention can be characterized providing a method of manufacturing a semiconductor device that can increase productivity. It will be appreciated, however, that the features of the present invention are not limited to those mentioned above, and other features of the present invention will be apparently understood by those skilled in the art through the following description.

One embodiment of the present invention can be exemplarily characterized as a semiconductor device that includes a semiconductor substrate and a plurality of recess trenches extending along a first direction in the semiconductor substrate. At least a portion of each of the plurality of recess trenches may include a pair of opposing intermediate sidewalls and a terminal sidewall connecting the opposing intermediate sidewalls. The pair of opposing intermediate sidewalls and the terminal sidewall may be defined in the semiconductor substrate. Terminal regions of at least one pair of adjacent plurality of recess trenches may be offset relative to each other along a second direction substantially perpendicular to the first direction.

Another embodiment of the present invention can be exemplarily characterized as a method of manufacturing a semiconductor device. The method may include forming a plurality of recess trenches within a semiconductor substrate that extend along a first direction. At least a portion of each of the plurality of recess trenches may include a pair of opposing intermediate sidewalls and a terminal sidewall connecting the opposing intermediate sidewalls. The pair of opposing sidewalls and the terminal sidewall may be defined in the semiconductor substrate. The terminal regions of at least one pair of adjacent recess trenches may be offset relative to each other along a second direction substantially perpendicular to the first direction.

Yet another embodiment of the present invention can be exemplarily characterized as a semiconductor device that includes a semiconductor substrate, a first recess trench defined in the semiconductor substrate and extending along a first direction and a second recess trench defined in the semiconductor substrate adjacent to the first recess trench and extending substantially along the first direction. Intermediate regions of the first and second recess trenches may be spaced apart from corresponding ends of the first and second recesses by terminal regions. The first and second recess trenches may be defined in the semiconductor substrate such that the intermediate region of the first recess trench is spaced apart from the intermediate region of the second recess trench along a second direction substantially perpendicular to the first direction by a first distance and such that the intermediate region of the first recess trench is spaced apart from the terminal region of the second recess trench along the second direction by a second distance, wherein the first distance is greater than the second distance.

### BRIEF DESCRIPTION OF THE DRAWINGS

The above and other features of the embodiments exemplarily described herein will become more apparent with reference to the attached drawings in which:

FIG. 1 is a cross-sectional view showing a recess channel array transistor in a semiconductor device according to one embodiment;

FIG. 2A is a perspective view showing a recess trench in the semiconductor device shown in FIG. 1;

FIG. 2B is a cross-sectional view taken along the line A-A′ of FIG. 2A;

FIG. 3 is a flowchart illustrating an exemplary method of manufacturing the semiconductor device shown in FIG. 1;

FIGS. 4A to 7 illustrate an exemplary method of manufacturing the semiconductor device shown in FIG. 1;

FIG. 8 is a cross-sectional view showing a spherical recess channel array transistor in a semiconductor device according to another embodiment;

FIG. 9 is a flowchart illustrating an exemplary method of manufacturing the semiconductor device shown in FIG. 8; and

FIGS. 10 and 11 illustrate an exemplary method of manufacturing the semiconductor device shown in FIG. 8.

### DETAILED DESCRIPTION

Exemplary embodiments of the present invention may be understood more readily by reference to the accompanying drawings. These embodiments may, however, be realized in many different forms and should not be construed as being limited to the embodiments set forth herein. Rather, these embodiments are provided so that this disclosure will be thorough and complete and will fully convey the concept of the invention to those skilled in the art, and the invention will only be defined by the appended claims. Like reference numerals refer to like elements throughout the specification.

As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

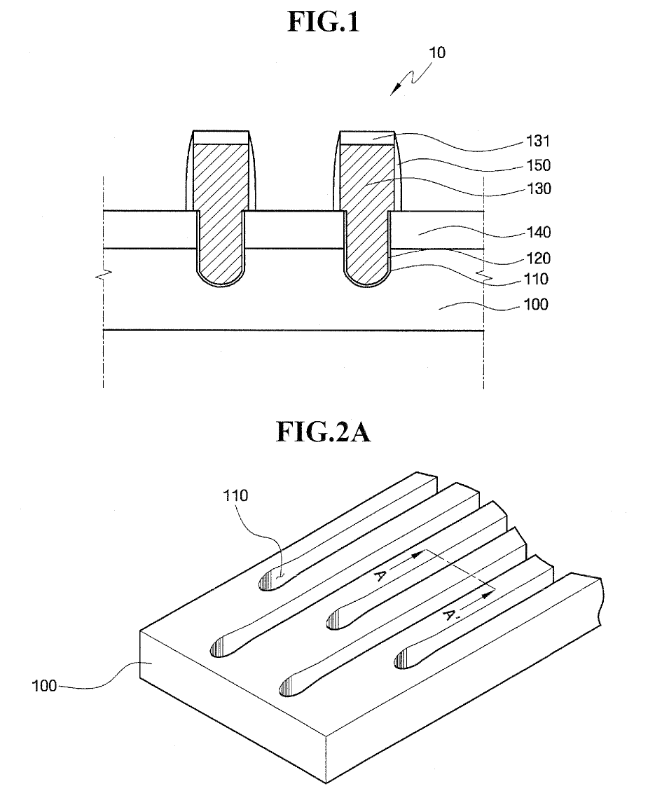

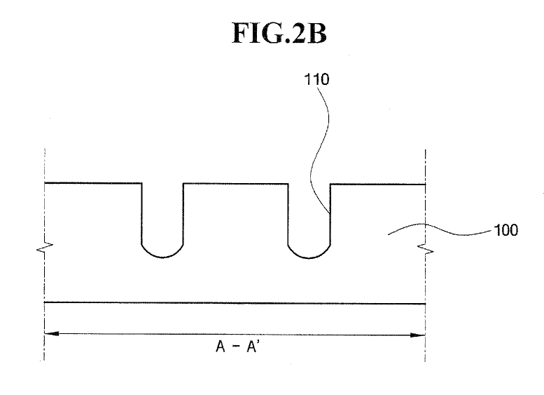

Hereinafter, a semiconductor device according to one embodiment will be described with reference to FIGS. 1 to 2B.

First, a recess channel array transistor in a semiconductor device according to one embodiment will be described with reference to FIG. 1. FIG. 1 is a cross-sectional view showing a recess channel array transistor in a semiconductor device according to one embodiment.

Referring to FIG. 1, a semiconductor substrate 100 may be divided into an active region and an isolation region by an isolation film formed of STI (Shallow Trench Isolation) or FOX (Field OXide). A recess channel array transistor 10 having a recess trench 110 may be formed on the active region.

In one embodiment, the recess channel array transistor 10 may, for example, include a recess trench 110, a gate insulating film 120, a gate electrode 130, a source/drain region 140, and spacers 150.

The recess trench 110 may be relatively narrow and deep within the semiconductor substrate 100. The recess trench 110 will be described below in detail.

The gate insulating film 120 may be formed on the inner surface of the recess trench 110. In one embodiment, the gate insulating film 120 may be substantially uniformly formed on the inner surface of the recess trench 110. The gate insulating film 120 may, for example, include a material such as silicon oxide (SiOₓ), silicon oxynitride (SiON), titanium oxide (TiOₓ), tantalum oxide (TaOₓ), or the like or a combination thereof.

The gate electrode 130 may be provided on the gate insulating film 120 so as to bury the recess trench 110 while protruding above the recess trench 110. The gate electrode 130 may be formed, for example, by sequentially laminating materials such as polysilicon, gate metal, or the like, on the gate insulating film 140. A capping film 131 may be formed at the upper part of the gate electrode 130. The width of a portion of the gate electrode 130 protruding above the recess trench 110 may be slightly larger than the width of the recess trench 110.

The source/drain region 140 (e.g., regions in which an impurity is implanted) may be provided in the active region on both sides of the gate electrode 130. In one embodiment, the recess channel array transistor 10 may be an N type transistor. In such an embodiment, the source/drain region 140 may be formed by ion-implanting an N-type impurity.

The spacers 150 may be provided at opposing side walls of the protruding portion of the gate electrode 130. The spacers 150 may, for example, include a material such as a nitride (e.g., SiN), an oxide (e.g., SiO₂), or the like or a combination thereof.

Next, a recess trench in the semiconductor device shown in FIG. 1 will be described in detail with reference to FIGS. 2A and 2B. FIG. 2A is a perspective view showing a recess trench in the semiconductor device shown in FIG. 1. FIG. 2B is a cross-sectional view taken along the line A-A′ of FIG. 2A.

The recess trenches 110 may be formed to be narrow and deep within the semiconductor substrate 100. A plurality of recess trenches 110 may be arranged to extend along one direction (also referred to herein as an “extension direction” or a “first direction) within the semiconductor substrate 100. In one embodiment, the recess trenches 110 may be formed such that terminal regions of adjacent recess trenches are offset from each other along a direction substantially perpendicular to the extension direction (also referred to herein as a “second direction”). As used herein, a “terminal region” of a recess trench generally refers to a region within the recess trench that extends from an end of the recess trench toward a central, intermediate region of the recess trench, along a direction defined by the major longitudinal axis of the recess trench, by a certain distance.

In one embodiment, the plurality of recess trenches 110 may be formed such that two adjacent recess trenches 110 having different terminal regions are alternatively arranged. That is, the terminal regions of the plurality of recess trenches 110 may be arranged in a zigzag manner along a direction substantially perpendicular to the extension direction.

In one embodiment, a width of the terminal region of each of the recess trenches 110 may be larger than a width of another region of each of the recess trenches 110 when the recess trench 110 is formed. Accordingly, if the terminal regions of adjacent recess trenches 110 are formed side by side, then adjacent recess trenches 110 may be connected to each other to form a bridge, which may subsequently cause a defective semiconductor device.

In the illustrated embodiment, however, the terminal regions of adjacent recess trenches 110 are offset from each other in a direction substantially perpendicular to the extension direction. Accordingly, even though the width of a terminal region of each recess trench 110 may be larger than a width of another region (e.g., the “intermediate region”) of each recess trench 110, adjacent recess trenches 110 are not connected to each other, and thus a bridge does not occur. That is, the occurrence of a defective semiconductor device due to the bridge can be reduced, and thus productivity can be increased.

Hereinafter, a method of manufacturing a recess channel array transistor according to one embodiment of the invention will be described with reference to FIGS. 1 to 8B.

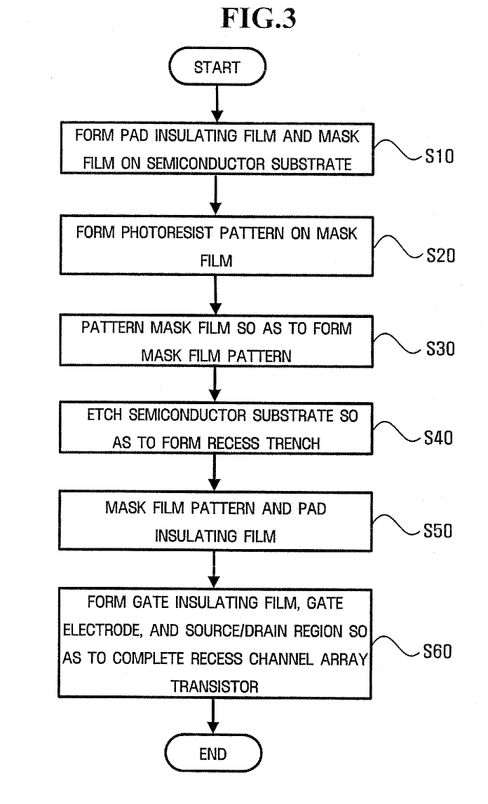

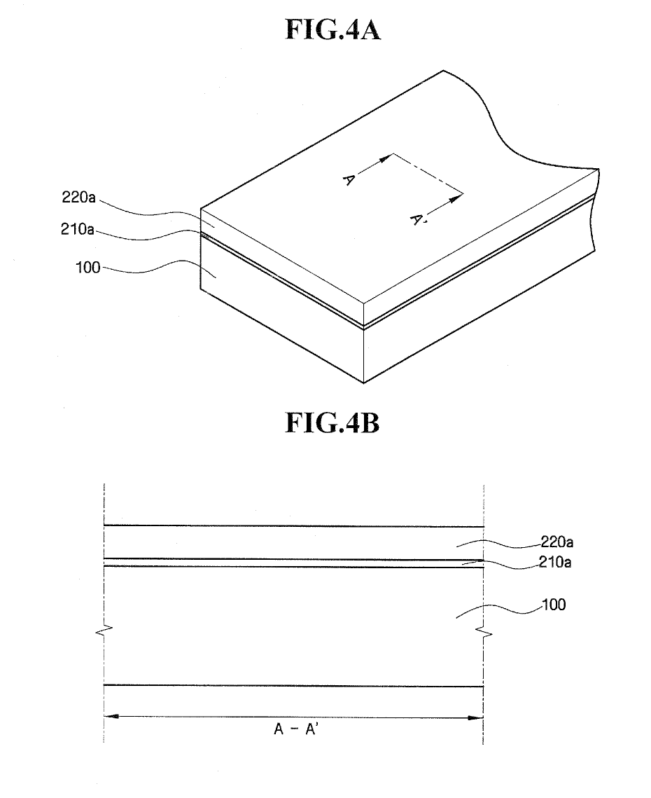

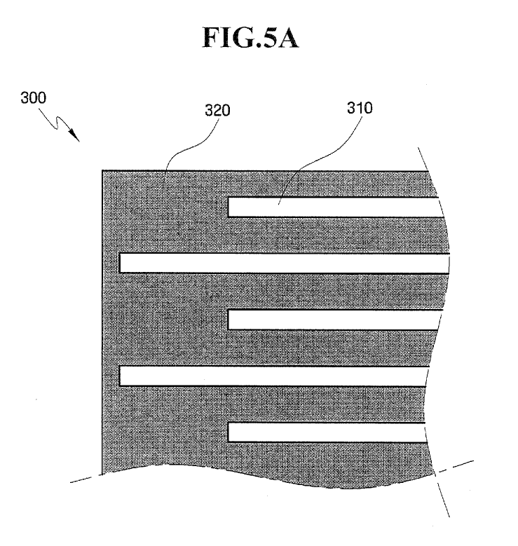

FIG. 3 is a flowchart illustrating a method of manufacturing the semiconductor device shown in FIG. 1. FIGS. 4A to 7 illustrate an exemplary method of manufacturing the semiconductor device shown in FIG. 1.

First, referring to FIGS. 3 to 4B, a pad insulating film 210a and a mask film 220a may be formed on the semiconductor substrate 100 (S10).

In one embodiment, the pad insulating film 210a may be formed using an oxidation process. For example, the pad insulating film 210a may include an MTO (Medium Temperature Oxide) film that is formed at a temperature of approximately 400° C. In one embodiment, the mask film 220a may be formed using a chemical vapor deposition method. For example, the mask film 220a may include a material polysilicon, SiN, SiON, or the like or a combination thereof.

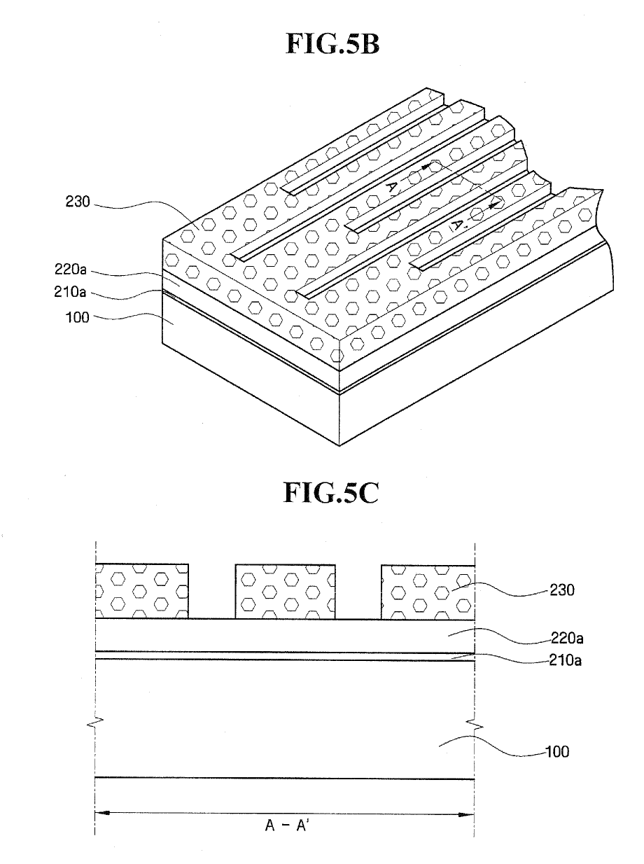

Next, referring to FIGS. 3, and 5A to 5C, a photoresist pattern 230 may be formed on the mask film 220a (S20).

In one embodiment, a photoresist may first be coated on the mask film 220a. Next, a photolithography process may be performed using a photomask 300 shown in FIG. 5A. As exemplarily shown in FIG. 5A, the photomask 300 may include a light-blocking pattern 320 in which transmissive regions 310, where the recess trenches 110 are to be subsequently formed, are defined. The transmissive regions 310 may be defined such that terminal regions of adjacent transmissive regions 310 in a direction substantially perpendicular to the extension direction are offset from each other.

Referring to FIGS. 5B and 5C, a photolithography process may then be carried out using the photomask 300 to form a photoresist pattern 230 on the mask film 220a. The photoresist pattern 230 may be formed such that only regions corresponding to the transmissive regions 310 of the photomask 300 are exposed. Accordingly, regions in the photoresist pattern 230 where the photoresist is removed are formed such that the terminal regions of adjacent regions in a direction substantially perpendicular to the extension direction may be offset from each other.

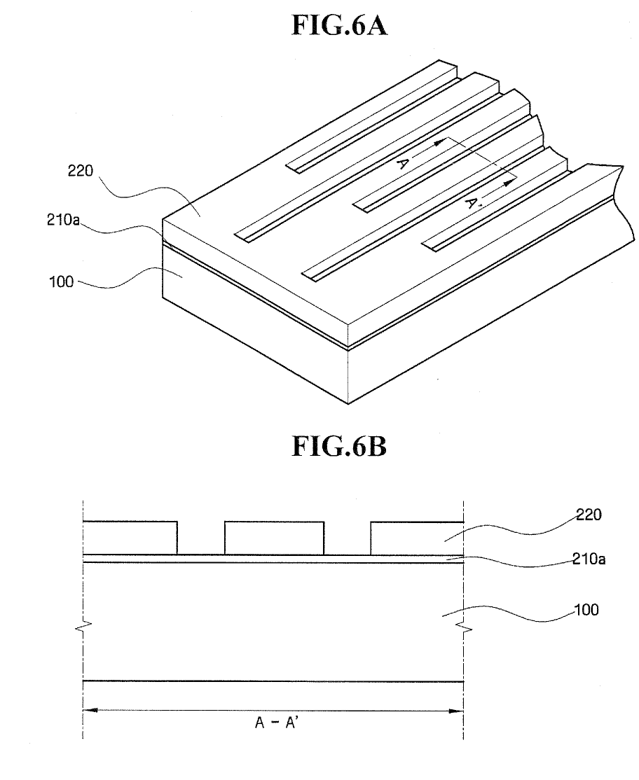

Next, referring to FIGS. 3, and 6A and 6B, the mask film 220a is patterned so as to form a mask film pattern 220 (S30).

In one embodiment, the mask film 220a may be patterned using the photoresist pattern 230 as an etching mask. The mask film pattern 220 may be formed to have substantially the same shape as the photoresist pattern 230. Accordingly, regions of the mask film pattern 220 may be formed such that the terminal regions of adjacent regions in a direction substantially perpendicular to the extension direction may be offset from each other. The photoresist pattern 230 may then be removed using, for example, an ashing process or the like.

Next, referring to FIGS. 3 and 7, the semiconductor substrate 100 may be etched so as to form the recess trenches 110 (S40).

In one embodiment, the pad insulating film 210a and the semiconductor substrate 100 may be etched using the mask film pattern 220 as an etching mask so as to form the recess trenches 110. The pad insulating film 210a and the semiconductor substrate 100 may be etched using, for example, dry etching techniques. Upon etching the pad insulating film 210a, a pad insulating film pattern 210 is formed.

Next, returning to FIGS. 2A to 3, the mask film pattern 220 and pad insulating film pattern 210 may be removed (S50). As a result, the plurality of recess trenches 110 that are formed in the semiconductor substrate 100 are exposed. Here, the plurality of recess trenches 110 are arranged along one direction (i.e., the extension direction) and the terminal regions of adjacent recess trenches 110 in a direction substantially perpendicular to the extension direction are offset each other. In one embodiment, the plurality of recess trenches 110 may be formed such that two adjacent recess trenches 110 having different terminal regions are alternatively arranged. That is, the terminal region of the plurality of recess trenches 110 may be arranged in a zigzag manner along a direction substantially perpendicular to the extension direction.

In one embodiment, an etching amount of the semiconductor substrate 100 at a location corresponding to the terminal regions of the recess trench 110 may be larger than at other locations corresponding to other regions of the recess trench 110. In another embodiment, the width of the terminal region of the recess trench 110 may be larger than a width of another region (e.g., the intermediate region) of the recess trench 110. However, because the terminal regions of adjacent recess trenches 110 are offset from each other, the terminal regions of adjacent recess trenches 110 can be prevented from being connected to each other. As a result, bridges can be prevented from occurring.

Next, returning to FIGS. 1 and 3, the gate insulating film 120, the gate electrode 130, and the source/drain region 140 may be formed such that the recess channel array transistor 10 is completed (S60).

In one embodiment, the gate insulating film 120 may first be substantially uniformly formed on the inner surface of the recess trench 110. The gate insulating film 120 may, for example, include silicon oxide, silicon oxynitride, titanium oxide, tantalum oxide, or the like or a combination thereof. The gate insulating film 120 may be deposited using, for example, a chemical vapor deposition method, a sputtering method, or the like or a combination thereof.

Next, the gate electrode 130 may be formed on the gate insulating film 120. The gate electrode 130 may, for example, be formed by depositing polysilicon and a metal layer, or the like, on the gate insulating film 120, forming a capping film 131, and then patterning the gate insulating film 120, the polysilicon and the metal layer, or the like, with the capping film 131.

Next, spacers 150 may be formed on the opposing sides of the gate electrode 130. The spacers 150 may, for example, by depositing a material such as silicon nitride (SiN), silicon oxide (SiO₂), or the like or a combination thereof, using a chemical vapor deposition (CVD) method and performing anisotropy etching.

Next, the source/drain region 140 may be formed to be aligned with the gate electrode 130 to complete the formation of the recess channel array transistor 10. The source/drain region 140 may be formed by implanting an impurity into the active region of the semiconductor substrate 100 at opposing sides of the gate electrode 130. In embodiments where the recess channel array transistor 10 is an N-type MOS transistor, the source/drain region 140 may be formed by implanting arsenic ions or phosphorous ions with a high concentration and energy of tens keV. In embodiments where the recess channel array transistor 10 is a P-type MOS transistor, boron ions may be implanted with a high concentration and energy of tens keV.

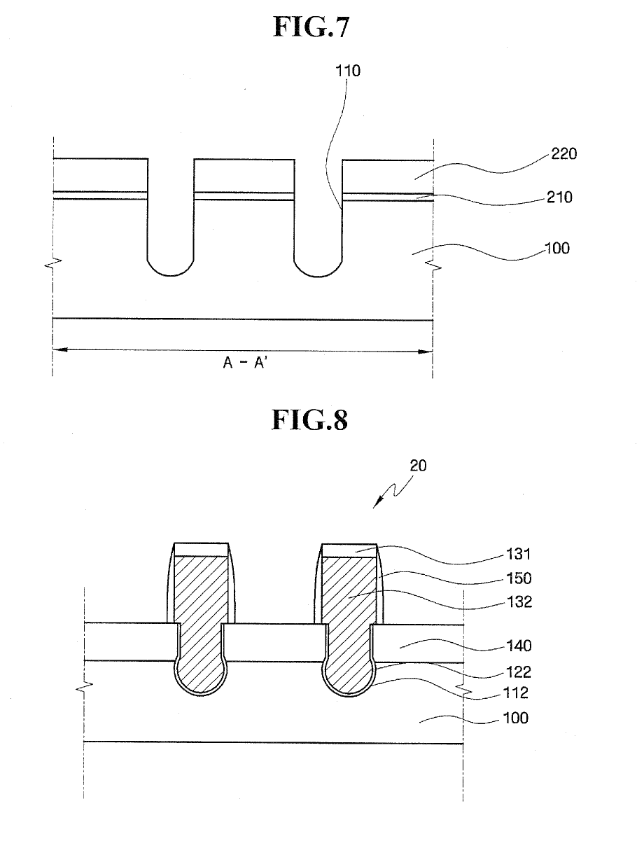

Hereinafter, a semiconductor device according to another embodiment will be described with reference to FIG. 8. FIG. 8 is a cross-sectional view showing a spherical recess channel array transistor in a semiconductor device according to another embodiment.

Elements shown in FIG. 8 which are the same as those in FIG. 1 are represented by the same reference numerals, and the descriptions thereof will be omitted. The semiconductor device according to another embodiment can be characterized as being different from the semiconductor device shown in FIG. 1 in that a spherical recess trench is provided. As used herein, the term “spherical” describes a shape as either substantially spherical or resembling a sphere (i.e., not substantially spherical).

Referring to FIG. 8, a semiconductor device according to another embodiment may, for example, include a spherical recess channel array transistor 20 having a spherical recess trench 112.

The spherical recess trench 112 is a recess trench having a spherical bottom. A plurality of spherical recess trenches 112 may be arranged to extend along one direction (also referred to herein as an “extension direction) within the semiconductor substrate 100. Further, the spherical recess trenches 112 may be formed such that terminal regions of adjacent spherical recess trenches 112 in a direction substantially perpendicular to the extension direction are offset from each other.

The plurality of spherical recess trenches 112 may be formed such that two adjacent spherical recess trenches 112 having offset terminal regions are alternatively arranged. That is, the terminal regions of the plurality of spherical recess trenches 112 may be arranged in a zigzag manner along a direction substantially perpendicular to the extension direction. The spherical recess trenches 112 may be arranged in essentially the same manner as the recess trenches shown in FIG. 2A.

Since the spherical recess trench 112 has a spherical bottom, a width of the spherical lower portion thereof may be larger than a width of an upper portion thereof (also referred to herein as a “general recess trench”). Accordingly, if the terminal region of adjacent spherical recess trenches 112 are formed side by side, adjacent spherical recess trenches 112 may be connected to each other to form a bridge, which may subsequently cause a defective semiconductor device.

In the illustrated embodiment, however, the terminal regions of adjacent spherical recess trenches 112 in a direction substantially perpendicular to the extension direction are offset from each other. Accordingly, even though the width of a terminal region of each spherical recess trench 112 is larger than a width of another region of each spherical recess trench 112, adjacent spherical recess trenches 112 are not connected to each other, and thus a bridge does not occur. Accordingly, the occurrence of a defective semiconductor device can be reduced, and thus productivity can be increased.

Because the spherical recess trench 112 has the spherical bottom, it has a radius of curvature that increases the surface area of relative to a general recess trench. As a result, the channel length increases. Further, as the radius of curvature of the spherical recess trench 112 increases, the concentration of an electric field can be reduced or eliminated and a refresh time characteristic can be improved. In addition, because the channel length increases and the refresh time characteristic is improved, the transistor can operate more stably.

In the semiconductor device shown in FIG. 8, because the occurrence of the bridge due to the connection of adjacent spherical recess trenches 112 is reduced, a spherical recess channel array transistor 20 having superior characteristics compared to conventional recess channel array transistors can be more stably formed. Therefore, the percent defective can be reduced, and productivity can be increased.

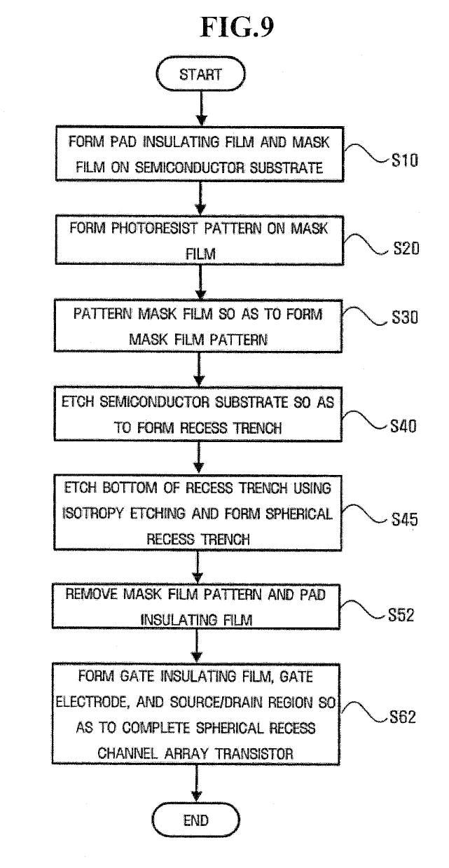

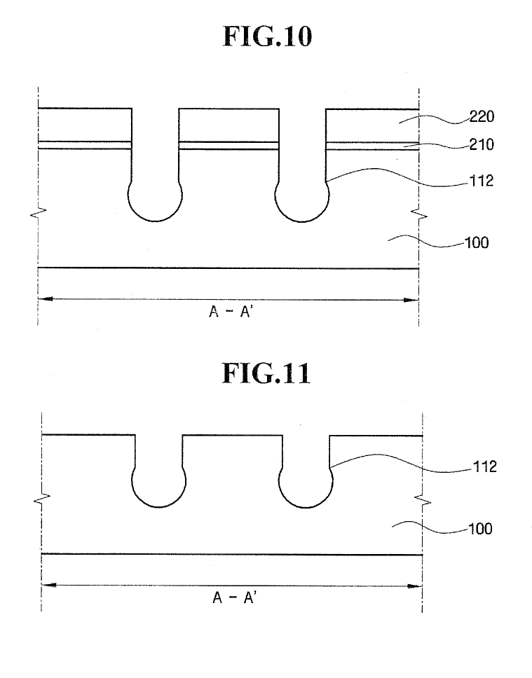

Hereinafter, an exemplary method of manufacturing a semiconductor device shown in FIG. 8 will be described with reference to FIGS. 8 to 11. FIG. 9 is a flowchart illustrating an exemplary method of manufacturing the semiconductor device shown in FIG. 8. FIGS. 10 and 11 are cross-sectional views illustrating an exemplary method of manufacturing the semiconductor device shown in FIG. 8.

The method of manufacturing a semiconductor device according to another embodiment of the invention differs from the method of manufacturing a semiconductor device shown in FIG. 1 in that the semiconductor device shown in FIG. 8 has the spherical recess trenches.

Aforementioned steps S10 to S40 may be the same as those in an embodiment of the invention, and thus only subsequent steps will be described.

Referring to FIGS. 9 and 10, the bottom of the recess trench 110 may be etched using an isotropic etching technique so as to form the spherical recess trench 112 (S45). In one embodiment, the isotropic etching technique may include dry etching.

Next, referring to FIGS. 9 and 11, the mask film pattern 220 and the pad insulating film 210a may be removed (S52). Then, the plurality of spherical recess trenches 112 that are formed in the semiconductor substrate 100 are exposed.

Next, returning to FIGS. 8 and 9, the gate insulating film 120, the gate electrode 130, and the source/drain region 140 may be formed in the spherical recess trench 112 such that the spherical recess channel array transistor 20 is completed (S62).

According to the embodiments exemplarily described above, bridges are not formed as a result of connections between adjacent recess trenches. Consequently, the occurrence of defective semiconductor devices can be reduced and the productivity can be increased. Moreover, the occurrence of bridge formed as a result of connections between adjacent spherical recess trenches is reduced. As a result, spherical recess channel array transistors having superior characteristics to conventional recess channel array transistors can be more stably formed.

Although embodiments of the present invention have been described in connection with the accompanying drawings, it will be apparent to those skilled in the art that various modifications and changes may be made thereto without departing from the scope and spirit of the invention. Therefore, it should be understood that the above embodiments are not limitative, but illustrative in all aspects.

What is claimed is:

1. A semiconductor device comprising:
a semiconductor substrate; and
a plurality of recess trenches extending along a first direction in the semiconductor substrate, wherein at least a portion of each of the plurality of recess trenches includes a pair of opposing intermediate sidewalls and a terminal sidewall connecting the opposing intermediate sidewalls,
wherein the pair of opposing intermediate sidewalls and the terminal sidewall are defined in the semiconductor substrate, and
wherein terminal regions of at least one pair of adjacent plurality of recess trenches are offset relative to each other along a second direction substantially perpendicular to the first direction.

2. The device of claim 1, wherein the at least one pair of adjacent recess trenches having offset terminal regions are repeatedly arranged.

3. The semiconductor device of claim 1, wherein terminal regions of the plurality of recess trenches are arranged in a zigzag manner along the second direction.

4. The semiconductor device of claim 1, wherein at least one of the recess trenches comprises a spherical recess trench.

5. The semiconductor device of claim 1, wherein a width of the terminal region of at least one recess trench of the pair of adjacent recess trenches is larger than a width of another region of the at least one recess trench of the pair of adjacent recess trenches.

6. The semiconductor device of claim 1, further comprising:
a gate insulating film disposed on an inner surface of at least one of the plurality of recess trenches;
a gate electrode disposed on the gate insulating film; and
a source/drain region disposed to be aligned with the gate electrode.

7. A method of manufacturing a semiconductor device, the method comprising:
forming a plurality of recess trenches within a semiconductor substrate, the plurality of recess trenches extending along a first direction,
wherein at least a portion of each of the plurality of recess trenches includes a pair of opposing intermediate sidewalls and a terminal sidewall connecting the opposing intermediate sidewalls,
wherein the pair of opposing sidewalls and the terminal sidewall are defined in the semiconductor substrate, and
wherein terminal regions of at least one pair of adjacent recess trenches are offset relative to each other along a second direction substantially perpendicular to the first direction.

8. The method of claim 7, wherein the plurality of recess trenches are formed such that the at least one pair of adjacent recess trenches having offset terminal regions are repeatedly arranged.

9. The method of claim 7, wherein terminal regions of the plurality of recess trenches are arranged in a zigzag manner along the second direction.

10. The method of claim 7, wherein forming the plurality of recess trenches comprises:
forming a pad insulating film and a mask film on the semiconductor substrate;
patterning the mask film so as to form a mask film pattern; and
etching the pad insulating film and the semiconductor substrate with the mask film pattern as an etching mask so as to form the recess trenches.

11. The method of claim 7, wherein at least one of the plurality of recess trenches comprises a spherical recess trench.

12. The method of claim 11, wherein forming the spherical recess trench comprises:
forming a pad insulating film and a mask film on the semiconductor substrate;
patterning the mask film so as to form a mask film pattern;
etching the pad insulating film and the semiconductor substrate with the mask film pattern as an etching mask so as to form at least one recess trench; and
isotropically etching a bottom portion of the at least one recess trench.

13. The method of claim 7, wherein a width of the terminal region of at least one recess trench of the pair of adjacent recess trenches is larger than a width of another region of the at least one recess trench of the pair of adjacent recess trenches.

14. The method of claim 7, further comprising, after the plurality of recess trenches are formed:
forming a gate insulating film on an inner surface of at least one of the recess trenches;
forming a gate electrode on the gate insulating film; and
forming a source/drain region adjacent to the gate electrode.

15. A semiconductor device comprising:
a semiconductor substrate;
a first recess trench defined in the semiconductor substrate and extending along a first direction; and
a second recess trench defined in the semiconductor substrate adjacent to the first recess trench and extending substantially along the first direction;
wherein intermediate regions of the first and second recess trenches are spaced apart from corresponding ends of the first and second recesses by terminal regions, and
wherein the first and second recess trenches are defined in the semiconductor substrate such that the intermediate region of the first recess trench is spaced apart from the intermediate region of the second recess trench along a second direction substantially perpendicular to the first direction by a first distance and such that the intermediate region of the first recess trench is spaced apart from the terminal region of the second recess trench along the second direction by a second distance, wherein the first distance is greater than the second distance.

16. The semiconductor device of claim 15, wherein a width of the terminal region of the second recess trench along the second direction is greater than a width of the intermediate region of the second recess trench along the second direction.

17. The semiconductor device of claim 15, further comprising a plurality of first and second recess trenches alternately arranged within the semiconductor substrate.
